(19) United States
(12) Patent Application Publication
(10) Pub. No.: US 2011/0279406 A1
(43) Pub. Date: Nov. 17, 2011

(54) CAPACITANCE SENSOR AND INFORMATION INPUT APPARATUS

(75) Inventors: Hiroto Kawaguchi, Miyagi (JP); Ryota Kitamura, Miyagi (JP); Takashi Itaya, Miyagi (JP)

(73) Assignee: SONY CORPORATION, Tokyo (JP)

(21) Appl. No.: 13/102,221

(22) Filed: May 6, 2011

(30) Foreign Application Priority Data
May 13, 2010 (JP) P2010-111247

(51) Int. Cl. G06F 3/045; H01B 5/00; G01R 27/26

(52) U.S. Cl. 345/174; 324/658; 174/126.1

(57) ABSTRACT

A capacitance sensor is provided and includes at least one electrode group positioned within a sensor area. The electrode group including a first electrode, a second electrode, and a third electrode. The capacitance sensor also includes a drive section configured to measure capacitances of the first, second and third electrodes, and configured to determine position information of at least one object based on the measured capacitances. At least one of the electrodes includes a portion that both increases and decreases in height along a width direction of the sensor area.

### CROSS REFERENCES TO RELATED APPLICATIONS

The present application claims priority to Japanese Patent Application JP 2010-111247 filed on May 13, 2010, the entire contents of which is hereby incorporated by reference.

### BACKGROUND

The present disclosure relates to a capacitance sensor and an information input apparatus which are capable of detecting a contact or proximate position of a finger in accordance with changes in capacitance.

In recent years, there has been widespread usage of electronic apparatuses that detect a position of a finger in accordance with changes in capacitances and control screen display and apparatus operation. This kind of capacitance sensors generally determine a contact or proximate position of a finger in a flat plane by detecting changes in capacitance of a plurality of electrodes arranged in the flat plane.

For example, Japanese Patent Application Laid-open No. 59-119630 (p. 3, FIG. 5) (hereinafter, referred to as Patent Document 1) discloses a touch switch apparatus having an electrode structure with two triangular touch electrodes formed by dividing a rectangle into two parts along a diagonal line, the touch electrodes being arranged in a uniaxial direction so that oblique sides thereof are opposed to each other with a slight clearance therebetween. According to such an electrode structure, since an area of a finger overlapping each of the touch electrodes varies depending on a uniaxial position of the finger, it is possible to identify a contact position of the finger in accordance with rates of changes in capacitances of the touch electrodes. In addition, Japanese Patent Application Laid-open No. 59-121484 (p. 3, FIG. 5) (hereinafter, referred to as Patent Document 2) discloses a coordinate input apparatus having a plurality of rectangular touch electrodes arranged in a biaxial direction at predetermined intervals in a matrix of 4×4, to identify a biaxial contact position of a finger in accordance with rates of changes in capacitances of the touch electrodes.

### SUMMARY

However, in the electrode structure disclosed in Patent Document 1, if the touch electrodes are wider along the uniaxial direction, the oblique sides of the touch electrodes each form a gentle angle, which decreases detection resolution for a contact position of a finger. In the electrode structure disclosed in Patent Document 2, signal lines are connected to the touch electrodes and routed through the clearance between the electrodes. The signal lines are capacitively coupled to a finger as the touch electrodes are, and therefore the signal lines need to be made thin to suppress decrease of detection accuracy due to the capacitive coupling of the signal lines. However, making the signal lines thin increases electric resistance in the signal lines, which deteriorates the touch electrodes in sensitivity of capacitance change.

In light of such circumstances, it is desirable to provide a capacitance sensor and an information input apparatus which are capable of enhancing accuracy of biaxial position detection and preventing decrease of sensitivity resulting from the presence of wiring lines within a detection area.

In an embodiment, a conductive film includes an electrode group including a first electrode, a second electrode, and a third electrode. At least one of the electrodes includes a portion that both increases and decreases in height along a width direction of the electrode. In an embodiment, each of the electrodes includes a portion that gradually increases or decreases in height along the width direction of the electrodes. In an embodiment, a sum of a height of the first electrode, a height of the second electrode, and a height of the third electrode are at least substantially constant along the width direction of the electrodes. In an embodiment, shapes of the first and second electrodes at least substantially mirror one another with respect to a center line of the electrode group. In an embodiment, the first electrode and the second electrode are at least substantially triangular in shape. In an embodiment, the third electrode is at least substantially triangular in shape. In an embodiment, the conductive film further includes a plurality of the electrode groups arranged in an array. In an embodiment, the first electrode has an oblique side opposed to at least one of the second electrode and the third electrode. In an embodiment, the first electrode has a first electrode shape at least substantially that of an isosceles triangle, the second electrode has a second electrode shape at least substantially that of a right triangle, and the third electrode has a third electrode shape at least substantially that of a right triangle, and wherein a position of the second electrode at least substantially mirrors that of the third electrode. In an embodiment, the first electrode includes a first oblique side opposed to the second electrode, and a second oblique side opposed to the third electrode.

In another embodiment, a capacitance sensor includes at least one electrode group positioned within a sensor area, the electrode group including a first electrode, a second electrode, and a third electrode. The capacitance sensor also includes a drive section configured to measure capacitances of the first, second and third electrodes, and configured to determine position information of at least one object based on the measured capacitances. In this embodiment, at least one of the electrodes includes a portion that both increases and decreases in height along a width direction of the sensor area. In an embodiment, a width of the electrode group is at least substantially similar to a width of the sensor area. In an embodiment, each of the electrodes includes a portion that gradually increases or decreases in height along the width direction of the electrodes. In an embodiment, a sum of a height of the first electrode, a height of the second electrode, and a height of the third electrode are at least substantially constant along the width direction of the electrodes. In an embodiment, the first electrode has an oblique side opposed to at least one of the second electrode and the third electrode. In an embodiment, the first electrode has a first electrode shape at least substantially that of an isosceles triangle, the second electrode has a second electrode shape at least substantially that of a right triangle, and the third electrode has a third electrode shape at least substantially that of a right triangle, and wherein a position of the second electrode at least substantially mirrors that of the third electrode. In an embodiment, the first electrode includes a first oblique side opposed to the second electrode, and a second oblique side opposed to the third electrode. In an embodiment, the first electrode has a maximum height at a central part thereof in the width direction. In an embodiment, the first electrode has a minimum height at a central part thereof in the width direction. In an embodiment, the capacitance sensor further includes a plurality of the electrode groups positioned within the sensor area and arranged in an array.

In another embodiment, an information input apparatus includes a capacitance sensor including at least one electrode group positioned within a sensor area, the electrode group including a first electrode, a second electrode, and a third electrode. The information input apparatus also includes a drive section configured to measure capacitances of the first, second and third electrodes, and configured to determine position information of at least one object based on the measured capacitances. The information input apparatus further includes a control section configured to process the position information output from the drive section. In this embodiment, at least one of the electrodes includes a portion that both increases and decreases in height along a width direction of the sensor area. In an embodiment, the drive section includes a signal generation circuit for generating signal voltages to be supplied to the electrodes, and an arithmetic circuit for calculating capacitances of the electrodes and changes in the capacitances. In an embodiment, the control section is configured to generate control signals for controlling an image displayed on an operation screen of a display element in accordance with the position information output from the drive section, and to output the control signals to the display element.

In an embodiment, a capacitance sensor includes at least one electrode group positioned within a sensor area and including a plurality of electrodes. At least one of the electrodes extends at least substantially across a sensor area width of the sensor area. The capacitance sensor also includes a drive section configured to measure capacitances of the electrodes and concurrently determine position information for a plurality of objects aligned in a width direction of the sensor area.

In another embodiment a capacitance sensor includes at least one electrode group configured as a single layer and positioned within a sensor area. The electrode group includes a plurality of electrodes, where an electrode group is substantially similar to a sensor area width, and where an electrode group length is less than a sensor area length. The capacitance sensor also includes a drive section configured to measure capacitances of the electrodes and concurrently determine position information for a plurality of objects aligned in a width direction of the sensor area.

Additional features and advantages are described herein, and will be apparent from the following Detailed Description and the figures.

### BRIEF DESCRIPTION OF THE FIGURES

FIG. 1 is an exploded schematic perspective view of an information input apparatus in an embodiment;

FIG. 2 is a schematic plane view of a capacitance sensor in a first embodiment;

FIG. 3 is a plane view of a configuration of an electrode group in the capacitance sensor;

FIG. 4 is a diagram for describing an operation of the capacitance sensor;

FIG. 5 is a diagram for describing an operation of the capacitance sensor;

FIG. 6 is a diagram for describing an operation of the capacitance sensor;

FIG. 7 is a diagram for describing an operation of the capacitance sensor;

FIG. 8 is a plane view of an electrode structure of a comparative example;

FIG. 9 is a plane view of one experimental example of the embodiment;

FIG. 10 shows arithmetic expressions for use in the experimental example;

FIG. 11 is a diagram showing results of the experimental example;

FIG. 12 is a schematic plane view of a capacitance sensor in a second embodiment;

FIG. 13 is a schematic plane view of a capacitance sensor in a third embodiment;

FIG. 14 is a diagram for describing a modification example of the second embodiment;

FIG. 15 is a diagram for describing a modification example of the first embodiment;

FIG. 16 is a diagram for describing a modification example of the third embodiment;

FIG. 17 is a diagram for describing a modification example of the first embodiment; and

FIG. 18 is a diagram for describing a modification example of the third embodiment.

### DETAILED DESCRIPTION

Hereinafter, embodiments will be described with reference to the drawings.

### First Embodiment

[Information Input Apparatus]

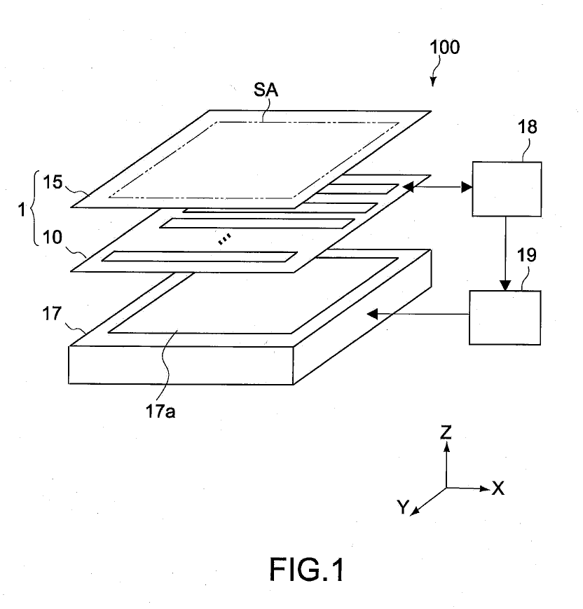

FIG. 1 is an exploded schematic perspective view of a configuration of an information input apparatus including a capacitance sensor in an embodiment. An information input apparatus 100 of this embodiment has a capacitance sensor 1, a display element 17, a drive section 18, and a control section 19. The information input apparatus 100 constitutes an electronic apparatus such as a portable information terminal or a stationary information display apparatus. In the figure, a case for housing the capacitance sensor 1, the display element 17, and the like, is not shown.

[Capacitance Sensor]

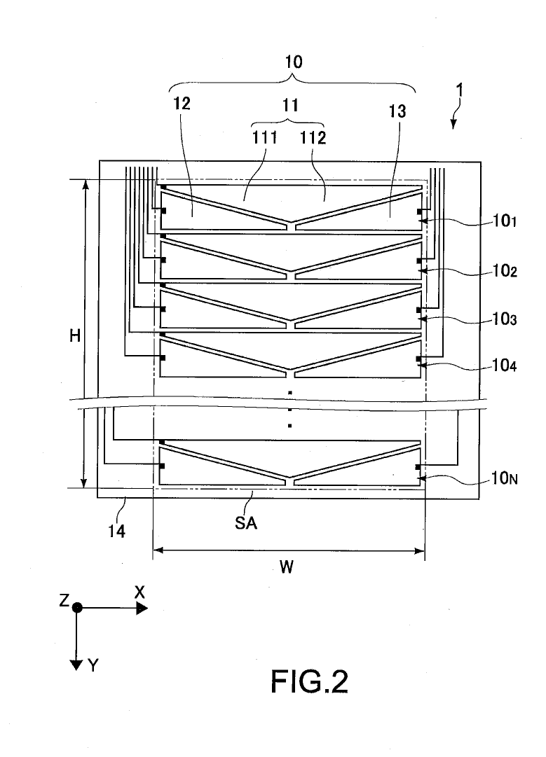

FIG. 2 is a schematic plane view of a configuration of the capacitance sensor 1. The capacitance sensor 1 has a detection area SA with a width W and a height H. The capacitance sensor 1 is placed on an operation screen 17a of the display element 17, and is configured as a sensor panel for detecting proximity or contact of a detection target (e.g. a user's finger) within the detection area SA in accordance with changes in capacitances. In FIGS. 1 and 2, an X axis denotes an axis parallel to a transverse side of the operation screen 17a, a Y axis denotes an axis parallel to a longitudinal side of the operation screen 17a, and a Z axis denotes an axis vertical to the operation screen 17a.

The capacitance sensor 1 has a plurality of electrode groups 10₁, 10₂, 10₃, 10₄, . . . , 10_{N} and a support body 14 for supporting these electrode groups as shown in FIG. 2. The electrode groups are arranged along the Y axis direction with a constant pitch on a surface of the support body 14. In FIG. 2, the electrode groups are given reference numerals 10₁, 10₂, 10₃, 10₄, . . . , 10_{N} in sequence along a +Y direction (second direction). The electrode groups are identical in configuration, and therefore are collectively called “electrode group 10” herein, except for the cases where the electrode groups are individually described.

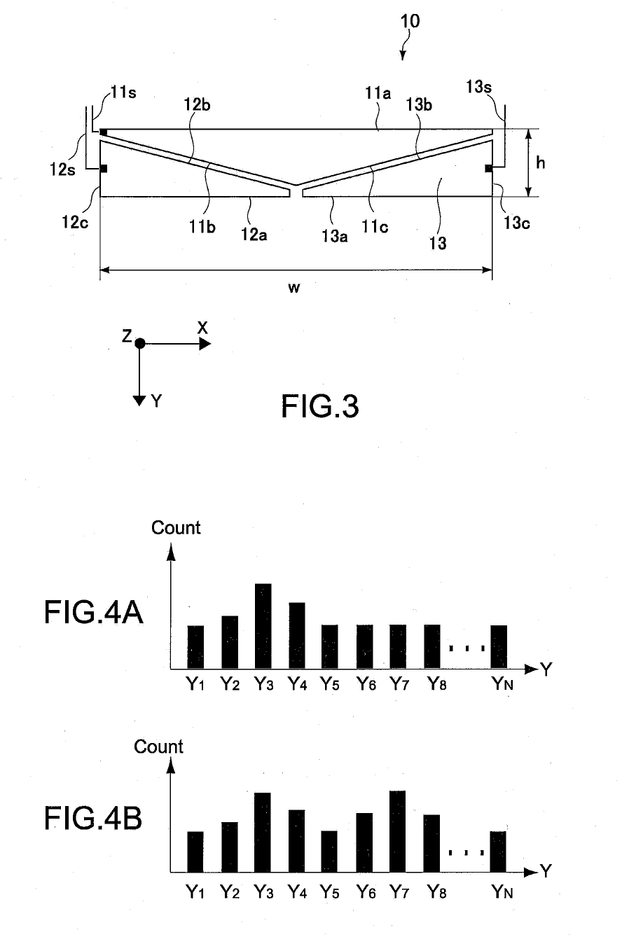

As shown in FIG. 2, the electrode group 10 is structured so that a rectangle with a width w and a height h is divided into three parts: a first electrode 11, a second electrode 12, and a third electrode 13. FIG. 3 is an enlarged plane view of one electrode group 10.

The first electrode 11 has a bottom side 11a parallel to the X axis direction. A length (w) of the bottom side 11a is made almost identical to the width W of the detection area SA. That is, the first electrode 11 is wide so as to cover the width of the detection area SA along the X axis direction.

The first electrode 11 has a first region 111 that is gradually larger in height parallel to the +Y direction (height direction) with respect to a width direction parallel to a +X direction, and a second region 112 that is gradually smaller in height with respect to the +X direction. In this embodiment, the first electrode 11 is formed of an approximate isosceles triangle having two oblique sides 11b and 11c with a maximum value of height at a central part thereof in the width direction.

The second electrode 12 is opposed to the first region 111 in the Y axis direction, and is gradually smaller in height parallel to the +Y direction (height direction) with respect to the +X direction (width direction). In this embodiment, the second electrode 12 is formed of an approximate right triangle that has a bottom side 12a parallel to the bottom side 11a of the first electrode 11 and almost half in width of the bottom side 11a, an oblique side 12b opposed to an oblique side 11b of the first electrode 11, and an adjacent side 12c adjacent to the former two sides. The oblique side 11b of the first electrode 11 and the oblique side 12b of the second electrode 12 form an identical angle of inclination with respect to the X axis. The two oblique sides 11b and 12b have a constant clearance therebetween. There is no particular limitation on size of the clearance, as far as the clearance provides electric isolation between the first region 111 and the second electrode 12.

The third electrode 13 is opposed to the second region 112 in the Y axis direction, and is gradually larger in height parallel to the +Y direction (height direction) with respect to the +X direction (width direction). In this embodiment, the third electrode 13 is formed of an approximate right triangle that has a bottom side 13a parallel to the bottom side 11a of the first electrode 11 and almost half in width of the bottom side 11a, an oblique side 13b opposed to the oblique side 11c of the first electrode 11, and an adjacent side 13c adjacent to the former two sides. The oblique side 11c of the first electrode 11 and the oblique side 13b of the third electrode 13 form an identical angle of inclination with respect to the X axis. The two oblique sides 11c and 13b have a constant clearance therebetween. There is no particular limitation on size of the clearance, as far as the clearance provides electrical isolation between the second region 112 and the third electrode 13.

The second electrode 12 and the third electrode 13 are opposed to each other in the X axis direction with a clearance therebetween, and are symmetrical with respect to a straight line parallel to the Y axis direction passing through the central part of the first electrode 11.

The support body 14 is opposed to an image display surface (operation screen 17a) of the display element 17. The support body 14 supports the electrode groups 10 configured as described above, so as to keep the electrode groups 10 arranged with a predetermined pitch in the Y axis direction. The support body 14 is formed of a flexible, electrical isolating plastic film of polyethylene terephthalate (PET), polyethylene naphthalate (PEN), polyimide (PI), polycarbonate (PC), or the like. Alternatively, the support body 14 may use a rigid material such as glass and ceramics.

The electrode group 10 (first to third electrodes 11 to 13) and the support body 14 are each formed of translucent materials. For example, the electrode group 10 is formed of a transparent conductive oxide such as indium tin oxide (ITO), SnO, and ZnO. The support body 14 is formed of a transparent resin film of PET, PEN, or the like. Accordingly, it is possible to see an image displayed on the operation screen 17a from the outside through the capacitance sensor 1.

There is no particular limitation on method for formation of the electrode groups 10. For example, a conductive film constituting the electrode group 10 may be formed on the support body 14, using a thin-film formation method such as vapor deposition, sputtering, and CVD. In this case, after formation of the conductive film on a substrate, the conductive film may be patterned in a predetermined shape. Alternatively, after formation of the conductive film on a surface of the substrate with a resist mask, an excessive conductive film may be removed (lifted off) together with the resist mask from the substrate. Besides, an electrode pattern may be formed on the substrate using a printing method such as plating and screen printing.

The electrode group 10 further has signal lines (wiring lines) for connecting the first to third electrodes 11 to 13 to the drive section 18. In this embodiment, as shown in FIG. 3, a signal line 11s is connected to one end of the first electrode 11 in the width direction, and signal lines 12s and 13s are connected to sides 12c and 13c of the second electrode 12 and the third electrode 13 directed toward the outside of the detection area SA, respectively.

The signal lines 11s to 13s are routed in an area outside of the detection area SA on the support body 14, and are connected to the drive section 18 via external connection terminals such as connectors not shown. In addition, the signal lines 11s to 13s are independently formed for each of the electrode groups 10, and are connected in common to the drive section 18.

The signal lines 11s to 13s may be formed of a constitutional material for the electrode group 10. In this case, the signal lines 11s to 13s can be formed simultaneously with formation of the electrode groups 10. Meanwhile, the signal lines 11s to 13s may be formed of a non-translucent conductive material, for example, metal lines of aluminum (Al), silver (Ag), copper (Cu), or the like. In this case, a wiring line layer can be made from a low-resistivity material, which allows detection of changes in capacitances of the electrode group 10 with high sensitivity. Further, since the signal lines 11s to 13s are positioned outside of the detection area SA, it is possible to prevent that the signal lines 11s to 13s impair image visibility as far as the outside of the detection area SA is out of an effective pixel area of the operation screen 17a.

The width w of the electrode group 10 is set to the width W of the detection area SA. The width w of the electrode groups 10 may be identical to, larger than, or smaller than the width W of the detection area SA. What matters is, one electrode group 10 covers the full width of the detection area SA, and two or more electrode groups 10 are not arranged in parallel with respect to the width direction of the detection area SA.

Meanwhile, the height h of the electrode group 10 is set as appropriate according to a height of the detection area SA, a size of a detection target, a detection resolution in the Y axis direction, or the like. In this embodiment, a user's finger is assumed as the detection target, and the height h is set to 5 to 10 mm, for example, in consideration of a size of a part of the finger in contact with the operation surface. Similarly, there is no particular limitation on the number of columns of the electrode groups 10 in the Y axis direction. The number of columns is set as appropriate according to the height of the detection area SA, the size of the detection target, the detection resolution in the Y axis direction, or the like.

In addition, as shown in FIG. 3, the total sum of the height of the first electrode 11 and the height of the second electrode 12 and the third electrode 13 is made constant with respect to the +X direction. This allows the height of the entire electrode group to be constant, thereby making it possible to suppress occurrence of variations in detection sensitivity depending on the position of the detection target with respect to the X axis direction.

Further, as shown in FIG. 1, the capacitance sensor 1 has a protection layer 15 for covering all the columns of the electrode groups 10. The protection layer 15 is formed of a translucent resin film of PET, PEN or the like, a plastic plate, a glass sheet, or the like. In addition, an outermost surface of the protection layer 15 constitutes an operation surface touched and operated by a user.

[Drive Section]

The drive section 18 driving the electrode group 10 includes a signal generation circuit for generating signal voltages to be supplied to the electrodes 11 to 13, and an arithmetic circuit for calculating capacitances of the electrodes 11 to 13 and changes in the capacitances. There is no particular limitation on signal voltages as far as the signals are capable of oscillating the electrodes 11 to 13. For example, the signals may be pulse signals with a predetermined frequency, high frequency signals, alternating current signals, or direct current signals. There is no particular limitation on arithmetic circuit as far as the arithmetic circuit is capable of detecting capacitances of the oscillating electrodes or amounts of changes in the capacitances. The arithmetic circuit of this embodiment converts amounts of changes in capacitances into integer values (count values), and outputs the same to the control section 19.

In this embodiment, a self-capacitance method is employed to detect capacitances and capacitance changes of the electrodes 11 to 13. The self-capacitance method is also called single-electrode method using only one electrode for sensing. The electrode for sensing has a floating capacitance with respect to a ground potential. When a grounded detection target such as a human body (a finger) comes close, the electrode increases in floating capacitance. The arithmetic circuit calculates proximity and position coordinates of a finger by detecting this capacitance increase.

There is no particular limitation on order of oscillation of the electrodes 11 to 13, that is, scanning method of the electrodes 11 to 13. The electrodes 11 to 13 may be oscillated in sequence in the width direction (+X direction) or in the opposite direction (−X direction). In addition, all the columns of the electrodes may be oscillated instantaneously or sequentially (in the Y direction, for example).

Further, the electrodes 11 to 13 of all the columns of the electrode groups 10 may not be oscillated at any time but may be oscillated with omission of predetermined electrodes. For example, only the first electrodes 11 of all the columns (or some of the columns with predetermined specific omissions) may be oscillated until proximity of the detection target (such as a user's finger) is detected, and then other electrodes may be oscillated with increasing proximity of the detection target. In addition, electrodes to be oscillated may be selected in a display mode of the operation screen 17a. For example, if images requiring input operations by a finger are densely located on the left side of the screen, only the second electrodes 12 of all the columns may be scanned, and in contrast, if those images are densely located on the right side of the screen, only the third electrodes 13 of all the columns may be scanned. This makes it possible to save the electrodes to be driven, as compared with the case where all the electrodes are scanned.

[Control Section]

The control section 19 generates control signals for controlling an image displayed on the operation screen 17a of the display element 17 in accordance with output from the drive section 18, and outputs the same to the display element 17. The control section 19 typically includes a computer which identifies an operating position, an operating direction, and the like of a finger in the detection area SA, and performs predetermined image control operations in accordance with these detection results. For example, the control section 19 performs screen control operations according to the user's intention, such as changing images on the screen correspondingly to the operating position and moving an image along the operating direction.

The control section 19 may generate other control signals for controlling other functions of the information input apparatus 100. For example, the control section 19 may allow various functions to be performed, such as telephone calling, line switching, dictionary searching, text information input, and game playing, depending on the operating position on the operation screen 17a.

The control section 19 may not necessarily be formed of a circuit separated from the drive section 18, but may include a circuit integrated with the drive section 18. For example, the control section 19 and the drive section 18 may be configured by a single semiconductor chip (IC chip).

[Example of Operation of Information Input Apparatus]

Next, an example of operation of the capacitance sensor 1 will be described below. Herein, a method for detecting an input operating position (XY coordinates) of a finger with the use of the capacitance sensor 1 will be explained. As described above, the control section 19 determines the input operating position.

(Detection in Y Axis Direction)

In the capacitance sensor 1, each of the electrode groups 10 constitute one detection group. Accordingly, the operating position in the Y axis direction is identified by detecting proximity or contact of the detection target in accordance with the total sum of capacitances or capacitance changes of the first to third electrodes 11 to 13 constituting the electrode group 10.

In this embodiment, for detection in the Y axis direction, for each electrode group 10 of all the columns, the total sum of capacitances (count amounts) of all the electrodes 11 to 13 is detected, and the contact position of the finger is identified with respect to the Y direction from the level of the total sum, using the following equation (1) for example:

Count(Y_{N})=(C₁₁+C₁₂C₁₃) (1)

In the equation (1), “C₁₁” denotes a count value of capacitance (or a change amount of capacitance) of the first electrode 11, “C₁₂” denotes a count value of capacitance (or a change amount of capacitance) of the second electrode 12, and “C₁₃” denotes a count value of capacitance (or a change amount of capacitance) of the third electrode 13. In addition, “Y_{N}” denotes column numbers (10₁, 10₂, 10₃, 10₄, . . . ) of the electrode groups 10 arranged in the Y axis direction, and “Count(Y_{N})” denotes the total sum of count values of capacitances (or change amounts of capacitances) of the electrodes 11 to 13 of the electrode groups 10 of all the columns.

FIG. 4A shows one example of a pattern of count values output from the electrode groups 10 of all the columns (10₁, 10₂, 10₃, 10₄, . . . 10_{N}). In detection of capacitances by the self-capacitance method, capacitances (floating capacitances) become larger with increasing proximity of the finger. Therefore, in this example, the electrode group 10₃ of the third column outputs a highest count value of capacitance, and it is thus possible to specify that the finger is in proximity to or in contact with a position immediately above the electrode group 10₃ with respect to the Y axis direction.

By setting an appropriate threshold for count value, it is possible to determine a proximity distance of the finger with respect to the capacitance sensor 1. Specifically, when a first threshold (touch threshold) is set for count value and a count value exceeds the threshold, it is determined whether a touch operation is performed by a finger on the operation screen 17a. In addition, a second threshold smaller than the first threshold may be set. This makes it possible to determine proximity of the finger before a touch operation, which allows detection of the finger's input operation in a non-contact manner.

In the example of a pattern of count values shown in FIG. 4B, the electrode group 10₃ of the third column and the electrode group 10₇ of the seventh column output a highest count value of capacitance. This example represents an input operation using two fingers (thumb and index finger, for example).

(Detection in X Axis Direction)

Next, a method for detecting an operating position on the operation screen 17a with respect to the X axis direction will be described below. For detection of an operating position with respect to the X axis direction, reference is made to changes in the capacitance (C₁₁) of the first electrode 11, changes in the capacitance (C₁₂) of the second electrode 12, and changes in the capacitance (C₁₃) of the third electrode 13.

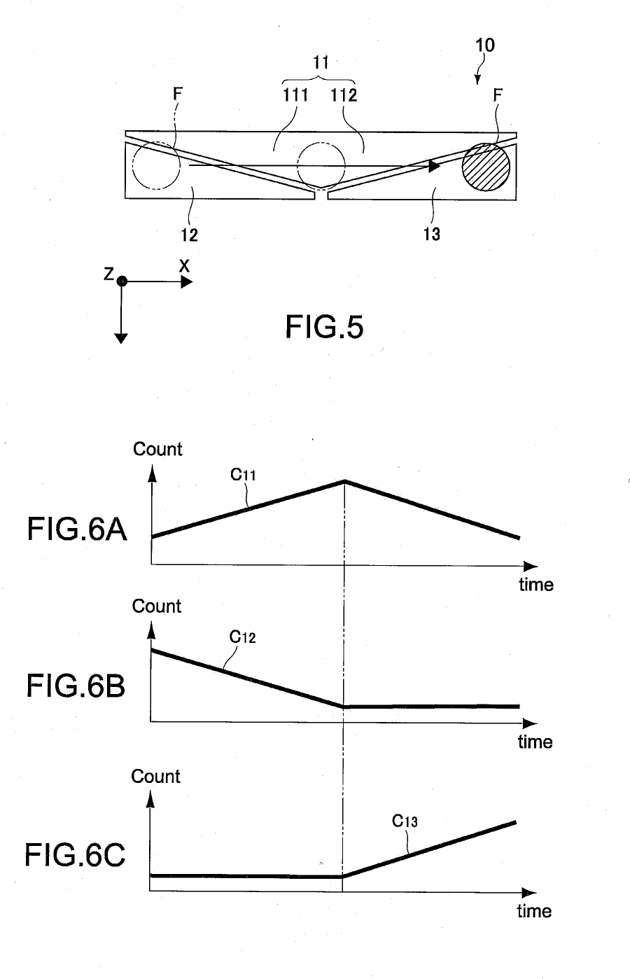

For example, when a finger F moves immediately above the electrode group 10 of an arbitrary column at a constant speed along the +X direction as shown in FIG. 5, capacitances of the electrodes 11 to 13 vary as shown in FIG. 6. FIG. 6A shows changes over time of capacitance (count value) of the first electrode 11, FIG. 6B shows changes over time of capacitance (count value) of the second electrode 12, and FIG. 6C shows changes over time of capacitance (count value) of the third electrode 13.

Assume that the finger F moves from the position shown by an alternate long and short dash line in FIG. 5 toward the central part of the electrode group 10 in the width direction. The first electrode 11 has the first region 111 that is gradually larger in height with respect to the +X direction, and the second electrode 12 is gradually smaller in height with respect to the +X direction. Therefore, along with the movement of the finger F in the +X direction, an area of overlap between the finger F and the first electrode 11 (first region 111) is gradually larger, and an area of overlap between the finger F and the second electrode 12 is gradually smaller. Since the value of capacitance is almost proportional to the size of an area of overlap with the finger F, the capacitance of the first electrode 11 is gradually larger and reaches a maximum value at the central part of the electrode group 10 in the width direction, as shown in FIG. 6A. In contrast, the capacitance of the second electrode 12 is gradually smaller and has a minimum value at the central part of the electrode group 10 in the width direction, as shown in FIG. 6B. Meanwhile, the third electrode 13 does not overlap the finger F and therefore has no change in capacitance.

Similarly, assume that the finger F moves from the central part of the electrode group 10 in the width direction to the position shown by a solid line in FIG. 5. The first electrode 11 has the second region 112 that is gradually smaller in height with respect to the +X direction, and the third electrode 13 is gradually larger in height with respect to the +X direction. Accordingly, along with the movement of the finger F in the +X direction, an area of overlap between the finger F and the first electrode 11 (second region 112) is gradually smaller, and an area of overlap between the finger F and the third electrode 13 is gradually larger. As a result, the capacitance of the first electrode 11 is gradually smaller as shown in FIG. 6A, whereas the capacitance of the third electrode 13 is gradually larger as shown in FIG. 6C. Meanwhile, the second electrode 12 does not overlap the finger F and therefore has no change in-capacitance.

According to this embodiment, since the electrode group 10 is constant in height (h) with respect to the width direction, it is possible to keep detection sensitivity of the finger F constant with respect to the X axis direction, regardless of an operating position of the finger F. In addition, since the first electrode 11 is formed in the shape of an isosceles triangle and the second and third electrodes 12 and 13 are symmetrically arranged, it is possible to eliminate variations in detection sensitivity between the first region 111 and the second region 112. Accordingly, the operating position of the finger F can be detected with high accuracy in the X axis direction.

In addition, according to this embodiment, the first electrode 11 and the second electrode 12 have straight oblique sides 11b and 12b as a boundary part therebetween, and the first electrode 11 and the third electrode 13 have straight oblique sides 11c and 13b as a boundary part therebetween, respectively. This provides stable detection sensitivity with predetermined proportional relations between the position of the detection target with respect to the width direction and the ratio of capacitance between the electrodes.

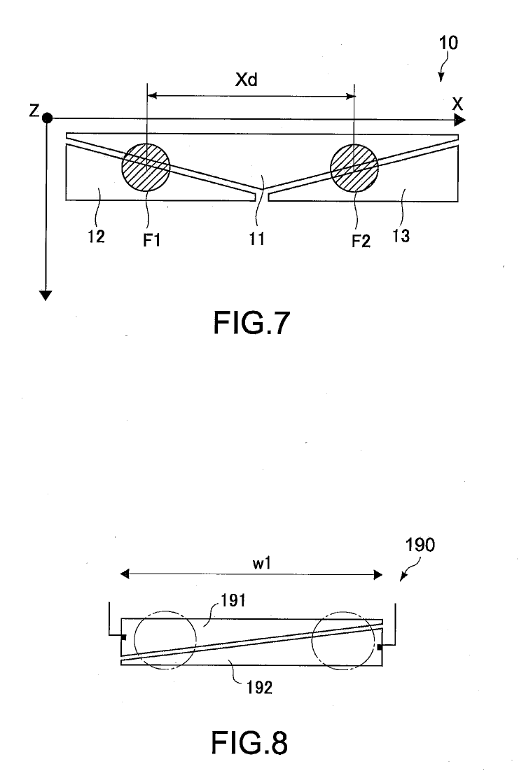

As described above, it is possible to identify the detection position of the finger F with respect to the X axis direction by comparing the magnitudes of capacitances of the first electrode 11, the second electrode 12, and the third electrode 13.

[1] If “C₁₂” is larger than the touch threshold and “C₁₃” is smaller than the touch threshold, it is determined that the finger F is positioned on the second electrode 12 side. In this case, the X coordinate of the finger F can be identified by calculating “C₁₂-C₁₁.” In contrast, if “C₁₂” is smaller than the touch threshold and “C₁₃” is larger than the touch threshold, it is determined that the finger F is positioned on the third electrode 13 side. In this case, the X coordinate of the finger F can be identified by calculating “C₁₃-C₁₁”

[2] If both “C₁₂” and “C₁₃” are smaller than the touch threshold and “C₁₁+C₁₂” or “C₁₁+C₁₃” is larger than the touch threshold, it is determined that the finger F is positioned near the central part of the first electrode 11. In this case, the X coordinate of the finger F can be identified by calculating “C₁₂-C₁₃.”

[3] If both “C₁₂” and “C₁₃” are larger than the touch threshold, it is determined that input operations are performed at two points: the second electrode 12 side and the third electrode 13 side. In this case, as shown in FIG. 7, an X coordinate of a finger F1 positioned on the second electrode 12 side and an X coordinate of a finger F2 positioned on the third electrode 13 side can be identified in the following manner. First, a distance Xd between the fingers F1 and F2 is calculated using the following equation (2):

Xd=ΣC₁₂+ΣC₁₃−ΣC₁₁ (2)

where ΣC₁₁ refers to the total sum of capacitances of the first electrodes 11 of the electrode groups 10 of all the columns Similarly, ΣC₁₂ refers to the total sum of capacitances of the second electrodes 12 of the electrode groups 10 of all the columns, and ΣC₁₃ refers to the total sum of capacitances of the third electrodes 13 of the electrode groups 10 of all the columns. By carrying out this calculation, it is possible to detect the distance between the fingers F1 and F2 with respect to the X axis direction with high accuracy even if the fingers F1 and F2 are positioned between a plurality of adjacent electrode groups 10.

Next, an approximate X coordinate of the finger F1 is identified from the value of “C₁₂,” and an approximate X coordinate of the finger F2 is identified from the value of “C₁₃,” and then these values of the X coordinates and the value of Xd are averaged to thereby determine X coordinates of the fingers F1 and F2. As the values of “C₁₂” and “C₁₃,” there can be used values of capacitances of the second electrode 12 and the third electrode 13, respectively, which are selected from an electrode group exceeding the touch threshold, out of the electrode groups 10 of all the columns.

In the above-mentioned manner, the X and Y coordinates of the input operating position are identified. There is no particular limitation on order in which the X and Y coordinates are identified, and therefore the X coordinate may be first identified or the Y coordinate may be first identified. Alternatively, according to the detection method in [3], the X and Y coordinates may be identified in parallel.

As described above, in the capacitance sensor 1 of this embodiment, the electrode group 10 is divided into three parts in the width direction of the detection area SA, which makes it possible to increase the rates of capacitance changes of all the electrodes according to changes in position of the detection target along the width direction. This increases accuracy of position detection of the detection target along the width direction, as compared with the case of using an electrode structure shown in FIG. 8, for example.

FIG. 8 shows a configuration of an electrode group 190 having a structure where a rectangle of a width w1 is divided into two parts along a diagonal line. In such an electrode structure, since a boundary line between two electrodes 191 and 192 with respect to the width direction is slightly inclined, the rates of changes in capacitances according to changes in operating position with respect to the width direction are lower as compared with the case of the tripartite electrode group 10 in this embodiment. This problem becomes further pronounced with increase of the width w1. Meanwhile, this embodiment can suppress a decrease in sensitivity of position detection due to increase of the width, as compared with the electrode structure of FIG. 8. In addition, this embodiment allows simultaneous detection of two operating positions as described above, which could not be realized by the electrode structure of FIG. 8.

In addition, according to this embodiment, the electrode groups 10 are arranged along the height direction of the detection area SA. Accordingly, it is possible to detect changes in position of the detection target in the height direction with high accuracy in accordance with the rates of changes in capacitances of the electrode groups 10.

Further, in this embodiment, the signal lines 11s to 13s to be connected to the electrodes are formed so that the electrodes constituting the electrode groups 10 of all the columns are directed toward the outside of the detection area with respect to the width direction. This eliminates the need to route the signal lines 11s to 13s within the detection area SA, thereby making it possible to prevent decrease in detection sensitivity or detection accuracy due to the presence of signal lines within the detection area SA.

### Experimental Example

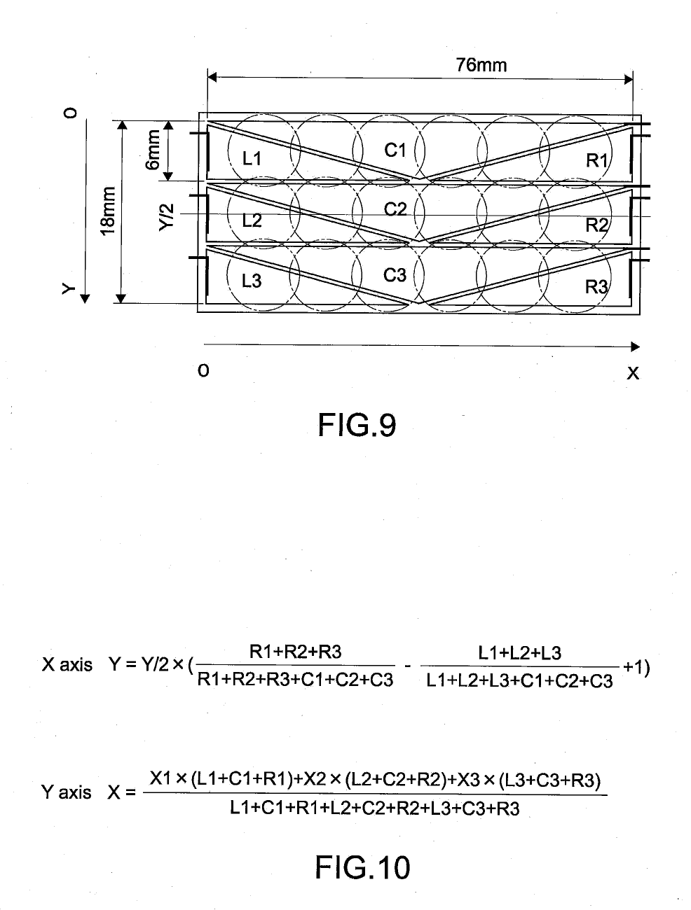

Characteristics of detection sensitivity of capacitances of electrodes in the prototype sensor were measured for a prototype of a capacitance sensor with dimensions and parts shown in FIG. 9. Three samples of electrode groups used for the experiment are each 76 mm in width parallel to the X axis direction and 6 mm in height parallel to the Y axis. The three samples were arranged with slight clearances therebetween in the Y axis direction. For the sake of convenience, among electrode patterns of the electrode groups of all the columns, the central electrode patterns are given reference numerals C1 to C3, the left electrode patterns are given reference numerals L1 to L3, and the right electrode patterns are given reference numerals R1 to R3. The individual electrode patterns were connected to self-capacitance drive ICs.

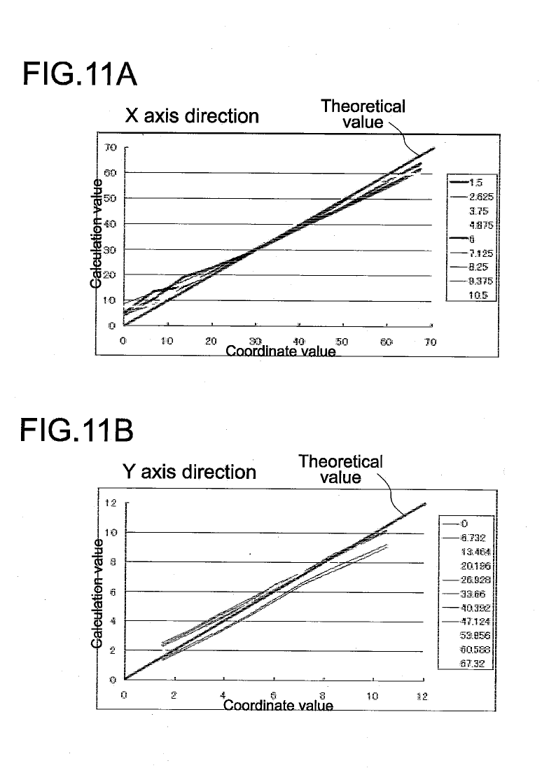

Next, a pseudo finger (metal bar) with a diameter of 8 mm at an end thereof was connected to a ground potential. The pseudo finger was moved with an end thereof over a plurality of parts of the sensor in parallel with the X axis direction and the Y axis direction. Then, when the pseudo finger has reached each of predetermined positions, count amounts of changes in capacitances of all the electrode patterns were measured. The obtained count change amounts were subjected to centroid computation using arithmetic expressions shown in FIG. 10. In FIG. 10, X1 denotes X coordinates of centroids of the electrode patterns C1, L1, and R1 of the first column, X2 denotes X coordinates of centroids of the electrode patterns C2, L2, and R2 of the second column, and X3 denotes X coordinates of centroids of the electrode patterns C3, L3, and R3 of the third column. Then, the coordinate values obtained by the calculations were compared with actual contact positions of the pseudo finger (theoretical values). FIGS. 11A and 11B show results of the comparison.

FIG. 11A describes measurement results with respect to the X axis direction, and FIG. 11B describes measurement results with respect to the Y axis direction. In each of the figures, the note on the right side shows position of the pseudo finger: FIG. 11A shows values of Y coordinate and FIG. 11B shows values of X coordinate. As shown in FIGS. 11A and 11B, the contact position of the pseudo finger can be calculated within a certain range of accuracy with respect to the actual contact position of the same. The accuracy of calculations can be actually improved by making several corrections to the calculations. Although in this experiment the arithmetic expressions of FIG. 10 are used to calculate the coordinates of the contact position, other arithmetic expressions may be used instead.

### Second Embodiment

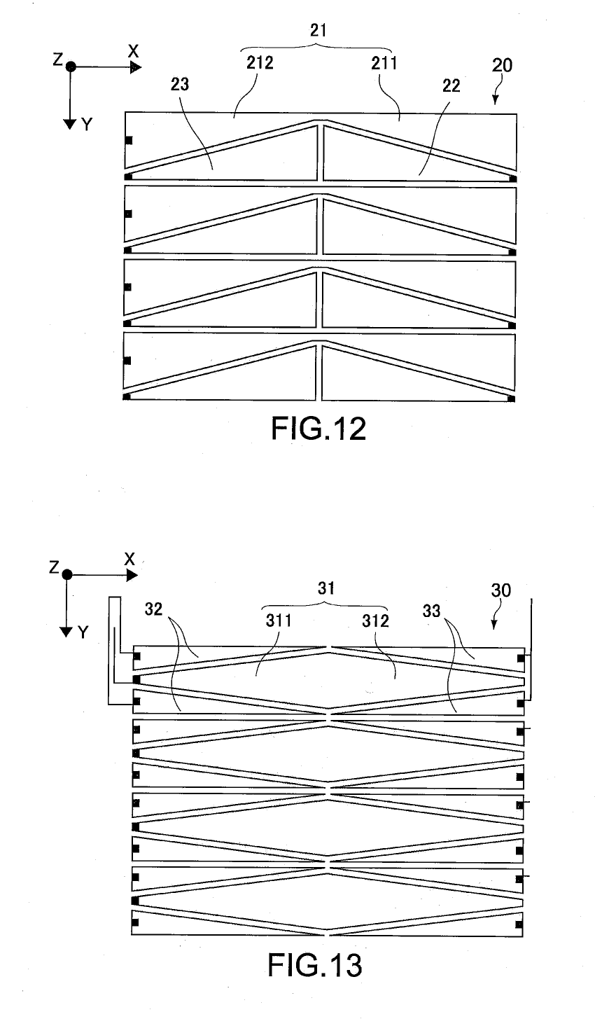

FIG. 12 is a schematic plane view of a capacitance sensor in a second embodiment. The capacitance sensor of this embodiment includes an electrode group 20 of a tripartite structure with a first electrode 21, a second electrode 22, and a third electrode 23, the electrode group 20 being arranged in the Y axis direction. FIG. 12 does not show a support body for supporting the electrode group 20.

In this embodiment, the first electrode 21 has a first region 211 that is gradually larger in height parallel to the Y axis direction with respect to the width direction parallel to the +X direction, and a second region 212 that is gradually smaller in height with respect to the +X direction. The second electrode 22 is opposed to the first region 211 in the Y axis direction and gradually smaller in height with respect to the +X direction. The third electrode 23 is opposed to the second region 212 in the Y axis direction, opposed to the second electrode 22 in the X axis direction, and gradually larger in height with respect to the +X direction. In addition, the second electrode 22 and the third electrode 23 are symmetrically arranged, and the first electrode 21 has a minimum value of height at a central part thereof in the width direction.

In the thus configured embodiment, a method for calculating an input position in accordance with capacitances of the electrodes 21 to 23 is different from the method in the first embodiment, but provides the same effects as that of the first embodiment.

### Third Embodiment

FIG. 13 is a schematic plane view of a capacitance sensor in a third embodiment. The capacitance sensor of this embodiment includes a tripartite electrode group 30 with a first electrode 31, a second electrode 32, and a third electrode 33, the electrode group 30 being arranged in the Y axis direction. FIG. 13 does not show a support body for supporting the electrode group 30.

In this embodiment, the first electrode 31 has a first region 311 that is gradually larger in height parallel to the Y axis direction with respect to the width direction parallel to the +X direction, and a second region 312 that is gradually smaller in height with respect to the +X direction. The second electrode 32 is opposed to the first region 311 in the Y axis direction and gradually smaller in height with respect to the +X direction. The third electrode 33 is opposed to the second region 312 in the Y axis direction, opposed to the second electrode 32 in the X axis direction, and gradually larger in height with respect to the +X direction. In addition, the second electrode 32 and the third electrode 33 are symmetrically arranged, and the first electrode 31 has a maximum value in height at a central part thereof in the width direction.

Further, in this embodiment, the second electrode 32 is divided with respect to the Y axis direction so as to sandwich the first region 311, and the third electrode 33 is divided with respect to the Y axis direction so as to sandwich the second region 312.

Even in the thus configured embodiment, the same effects as that in the first embodiment can be obtained. In particular, according to this embodiment, it is possible to suppress decrease in detection resolution with respect to the X axis direction and Y axis direction even if the electrode group 30 is comparatively larger in height.

In each of the above-mentioned embodiments, the capacitance sensor is disposed on the operation screen. Alternatively, the capacitance sensor may be solely installed in a case of an electronic apparatus, as with a touch pad or the like. In this case, the capacitance sensor does not necessarily need to be translucent, and therefore the electrodes of the sensor may be formed of a non-translucent material such as metal.

In the above-mentioned embodiment, the boundary parts between the electrodes constituting the electrode group are formed of straight oblique sides. Besides, the boundary parts may be configured in a zigzag form by which the height of the electrodes varies on a step-by-step basis. Alternatively, the boundary parts may be made inclined in a curved form. In this case, the sensor can be higher in detection resolution at the central part thereof than at the side parts thereof in the width direction.

In addition, in each of the above-mentioned embodiments, the first electrode is configured to have a maximum height at the central part thereof in the width direction or at the both ends thereof in the width direction. Alternatively, the maximum height can be changed as appropriate depending on demanded detection resolution in accordance with the specification of the apparatus.

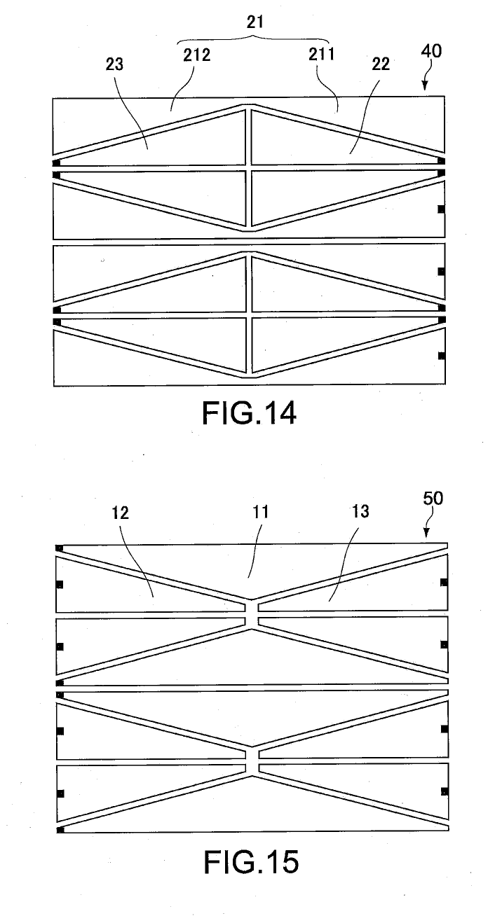

Further, the shapes of the first to third electrodes constituting the electrode group of all the columns of the capacitance sensor are not limited to the above-mentioned examples, and the first to third electrodes may be arranged in a reversed state in the height direction. Alternatively, as shown in FIGS. 14 and 15, the electrode section may be arranged alternately in the reversed state and the non-reversed state in the height direction. An electrode group 40 shown in FIG. 14 is equivalent to the electrode group in the second embodiment (refer to FIG. 12), and an electrode group 50 shown in FIG. 15 is equivalent to the electrode group in the first embodiment (refer to FIG. 2).

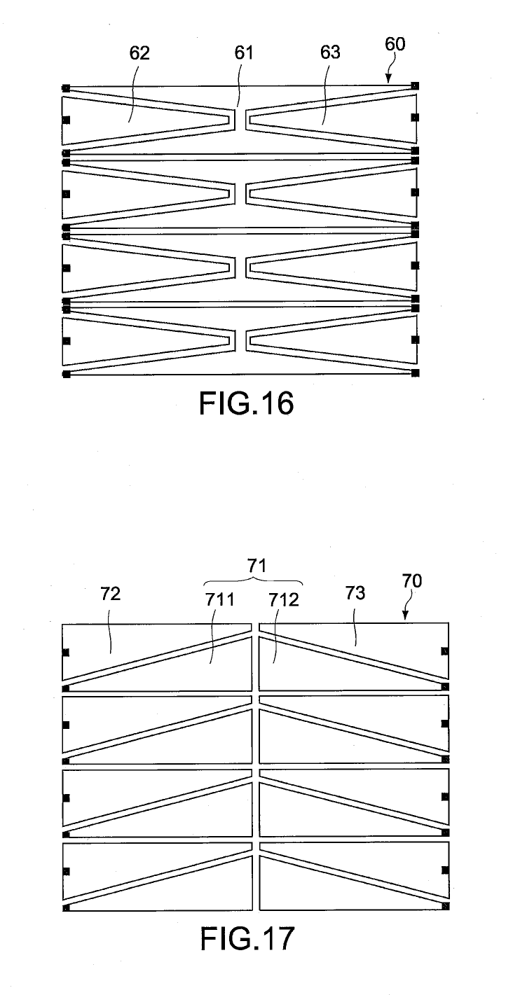

In an electrode group 60 shown in FIG. 16, a first electrode 61 is divided into two parts in the Y axis direction so as to sandwich a second electrode 62 and a third electrode 63. In this example, a part of the first electrode sandwiching the second electrode 62 is equivalent to the first region, and a part of the first electrode sandwiching the third electrode 63 is equivalent to the second region. Even in this configuration, the same effects as that in the third embodiment can be obtained.

In an electrode group 70 shown in FIG. 17, a first electrode 71 is divided into a first region 711 opposed to a second electrode 72 and a second region 712 opposed to a third electrode 73. Even in this configuration, the same effects as that in the above-mentioned embodiments can be obtained.

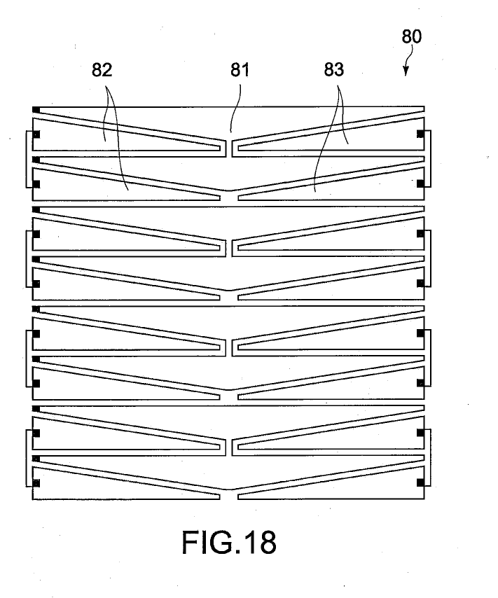

In an electrode group 80 shown in FIG. 18, a first electrode 81 is divided into two parts in the Y axis direction, and a second electrode 82 and a third electrode 83 are also divided into two parts. The first electrode 81 and the second electrode 82 are opposed to each other in the Y axis direction so as to sandwich each other, and similarly, the first electrode 81 and the third electrode 83 are opposed to each other in the Y axis direction so as to sandwich each other. Even in this example, a part of the first electrode sandwiching the second electrode 82 is equivalent to the first region, and a part of the first electrode sandwiching the third electrode 83 is equivalent to the second region. Even in this configuration, the same effects as that in the third embodiment can be obtained.

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A conductive film comprising:
an electrode group including
a first electrode,
a second electrode, and
a third electrode,
wherein at least one of the electrodes includes a portion that both increases and decreases in height along a width direction of the electrode.

2. The conductive film according to claim 1, wherein each of the electrodes includes a portion that gradually increases or decreases in height along the width direction of the electrodes.

3. The conductive film according to claim 1, wherein a sum of a height of the first electrode, a height of the second electrode, and a height of the third electrode are at least substantially constant along the width direction of the electrodes.

4. The conductive film according to claim 1, wherein shapes of the first and second electrodes at least substantially mirror one another with respect to a center line of the electrode group.

5. The conductive film according to claim 3, wherein the first electrode and the second electrode are at least substantially triangular in shape.

6. The conductive film according to claim 5, wherein the third electrode is at least substantially triangular in shape.

7. The conductive film according to claim 1, further comprising a plurality of the electrode groups arranged in an array.

8. The conductive film according to claim 1, wherein the first electrode has an oblique side opposed to at least one of the second electrode and the third electrode.

9. The conductive film according to claim 1, wherein the first electrode has a first electrode shape at least substantially that of an isosceles triangle, the second electrode has a second electrode shape at least substantially that of a right triangle, and the third electrode has a third electrode shape at least substantially that of a right triangle, and wherein a position of the second electrode at least substantially minors that of the third electrode.

10. The conductive film according to claim 9, wherein the first electrode includes a first oblique side opposed to the second electrode, and a second oblique side opposed to the third electrode.

11. A capacitance sensor comprising:
at least one electrode group positioned within a sensor area, the electrode group including
a first electrode,
a second electrode, and
a third electrode; and
a drive section configured to measure capacitances of the first, second and third electrodes, and configured to determine position information of at least one object based on the measured capacitances,
wherein at least one of the electrodes includes a portion that both increases and decreases in height along a width direction of the sensor area.

12. The capacitance sensor according to claim 11, wherein a width of the electrode group is at least substantially similar to a width of the sensor area.

13. The capacitance sensor according to claim 11, wherein each of the electrodes includes a portion that gradually increases or decreases in height along the width direction of the electrodes.

14. The capacitance sensor according to claim 11, wherein a sum of a height of the first electrode, a height of the second electrode, and a height of the third electrode are at least substantially constant along the width direction of the electrodes.

15. The capacitance sensor according to claim 11, wherein the first electrode has an oblique side opposed to at least one of the second electrode and the third electrode.

16. The capacitance sensor according to claim 11, wherein the first electrode has a first electrode shape at least substantially that of an isosceles triangle, the second electrode has a second electrode shape at least substantially that of a right triangle, and the third electrode has a third electrode shape at least substantially that of a right triangle, and wherein a position of the second electrode at least substantially mirrors that of the third electrode.

17. The capacitance sensor according to claim 16, wherein the first electrode includes a first oblique side opposed to the second electrode, and a second oblique side opposed to the third electrode.

18. The capacitance sensor according to claim 11, wherein the first electrode has a maximum height at a central part thereof in the width direction.

19. The capacitance sensor according to claim 11, wherein the first electrode has a minimum height at a central part thereof in the width direction.

20. The capacitance sensor according to claim 11, further comprising a plurality of the electrode groups positioned within the sensor area and arranged in an array.

21. An information input apparatus comprising:
a capacitance sensor including at least one electrode group positioned within a sensor area, the electrode group including
a first electrode,
a second electrode, and
a third electrode;
a drive section configured to measure capacitances of the first, second and third electrodes, and configured to determine position information of at least one object based on the measured capacitances; and
a control section configured to process the position information output from the drive section,
wherein at least one of the electrodes includes a portion that both increases and decreases in height along a width direction of the sensor area.

22. The information input apparatus according to claim 21, wherein the drive section includes a signal generation circuit for generating signal voltages to be supplied to the electrodes, and an arithmetic circuit for calculating capacitances of the electrodes and changes in the capacitances.

23. The information input apparatus according to claim 21, wherein the control section is configured to generate control signals for controlling an image displayed on an operation screen of a display element in accordance with the position information output from the drive section, and to output the control signals to the display element.

24. A capacitance sensor comprising:
at least one electrode group positioned within a sensor area and including a plurality of electrodes, at least one of the electrodes extending at least substantially across a sensor area width of the sensor area; and
a drive section configured to measure capacitances of the electrodes and concurrently determine position information for a plurality of objects aligned in a width direction of the sensor area.

25. A capacitance sensor comprising:
at least one electrode group configured as a single layer and positioned within a sensor area, the electrode group
including a plurality of electrodes,
having an electrode group width that is substantially similar to a sensor area width, and
having an electrode group length that is less than a sensor area length; and
a drive section configured to measure capacitances of the electrodes and concurrently determine position information for a plurality of objects aligned in a width direction of the sensor area.
